(19) United States
(12) Patent Application Publication
(10) Pub. No.: US 2026/0208241 A1
(43) Pub. Date: Jul. 23, 2026

(54) APPARATUS AND METHOD FOR CLEANING POT-SHAPED HOLLOW BODIES, IN PARTICULAR TRANSPORT CONTAINERS FOR SEMICONDUCTOR WAFERS OR FOR LITHOGRAPHY MASKS

(71) Applicant: GSEC GERMAN SEMICONDUCTOR EQUIPMENT COMPANY GMBH, Radolfzell am Bodensee (DE)

(72) Inventor: Lutz Rebstock, Gaienhofen (DE)

(21) Appl. No.: 19/112,981

(22) PCT Filed: Aug. 15, 2023
(86) PCT No.: PCT/EP2023/072447

§ 371 Date: Mar. 19, 2025

(30) Foreign Application Priority Data
Sep. 22, 2022 (DE) 10 2022 124 334.6

(51) Int. Cl. B08B 9/28; B08B 7/02; B08B 13/00; F26B 21/00; G03F 1/66; H10P 72/10

(52) U.S. Cl. CPC B08B 9/28; B08B 7/026; B08B 13/00; F26B 21/00; G03F 1/66; B08B 2209/08; H10P 72/19

(57) ABSTRACT

The present invention relates to a device for cleaning pot-shaped hollow bodies, wherein the device comprises a support wall on which the hollow body can be placed; at least one passage opening formed by the support wall; a cleaning device by which a cleaning fluid for cleaning the cover support surface can be dispensed when the hollow body is placed on the support wall, with the cleaning device having a cleaning head that projects over the passage opening when the hollow body is placed on the support wall; and a number of cleaning nozzles through which the cleaning fluid can be applied to the cover support surface. The invention further relates to a method of cleaning pot-shaped hollow bodies using such a device.

### BACKGROUND

### Field of the Invention

The present invention relates to a device for drying pot-shaped hollow bodies, in particular transport containers for semiconductor wafers or for EUV lithography masks.

### Description of the Related Art

The manufacture of highly integrated electronic circuits and other sensitive semiconductor components takes place today in factories in which so-called semiconductor wafers run through a large number of processing steps. A large part of these processing steps takes place in clean rooms that are kept free of contaminants, in particular free of particles, with a high effort. Such a complex processing is necessary since particles that come into contact with the semiconductor material of the semiconductor wafers can in particular influence the material properties of the semiconductor wafers such that a total production batch becomes defective and unusable and has to be scrapped.

Since the keeping clean is becoming more and more important as the integration density of the semiconductor circuits increases and the effort to keep clean increases exponentially as the size of the clean rooms increases, the semiconductor wafers are not transported from one processing station to the next in an “open” state. Special transport containers (so-called FOUPs, front opening unified pods) are used instead. They are understood as box-shaped transport containers into which a large number of semiconductor wafers is inserted. The FOUPs are typically closed by a removable cover. Without the cover the FOUPs have a pot-shaped basic shape with a rectangular base surface. When the FOUPs are closed by their lids, the inserted semiconductor wafers can be transported from one clean room to another clean room protected from the environment. When the FOUPs have reached a processing station, they are opened, the semiconductor wafers are removed, and are processed accordingly. After processing has taken place, the semiconductor wafers are transported back into the FOUPs and are then conveyed to the next processing station.

Due to the high production downtimes on contaminations of the semiconductor wafers, it is necessary to clean the FOUPs from time to time. The FOUPs are in particular contaminated by the wear debris of the semiconductor wafers on the introduction into and the removal from the FOUPs.

The same applies accordingly to the transport containers for EUV lithography masks (“extreme ultraviolet radiation”). The EUV lithography masks are used to manufacture very small integrated circuits. The EUV lithography masks, like the semiconductors, also have to be transported, with a similar situation arising. When FOUPs are spoken of in the following, the statements in this respect apply equally to transport containers for EUV lithography masks.

Devices for cleaning FOUPs are known, for example, from WO 2006/136224 A1, WO 2005/001888 A2, and DE 10 2020 129 469 A1. With such devices, the FOUPs can be cleaned both on both their inner surfaces and their outer surfaces. As mentioned, the FOUPs are closed by a cover that is only removed when the semiconductor wafers have been introduced into the FOUPs or have been removed from them. The FOUPs are typically contaminated much more strongly on their outer surfaces than on their inner surfaces. The cover support surface plays a particular role here. In the FOUPs presented in DE 10 2020 129 469 A1, for example, the cover support surface is located between the inner surface and the outer surface. With more modern FOUPs, however, the cover support surface is formed by a step of the inner surface so that the cover is positioned by the inner surface when the cover is placed on the cover support surface. Contaminants originating from the cover collect on the cover support surface due to the contact with the cover. As a consequence, the cover support surface is contaminated more than the remaining inner surface. Contaminants that are arranged on the inner surface can, however, be deposited directly on the semiconductor wafers and can develop the above-described effects.

### SUMMARY

It is an object of an embodiment of the present invention to provide a device for cleaning a pot-shaped hollow body by which it is possible using simple and inexpensive means to provide a remedy for the above-named disadvantages and in particular to reduce the number of defective and unusable production batches of semiconductor wafers. It is furthermore an underlying object of an embodiment of the present invention to provide a method by which such a device can be operated.

This object is achieved by the features specified in claims 1 and 11. Advantageous embodiments are the subject of the dependent claims.

An embodiment of the invention relates to a device for cleaning pot-shaped hollow bodies, in particular transport containers for semiconductor wafers or for EUV lithography masks, wherein the hollow body comprises a base wall and one or more side walls that form an inner hollow body surface; and an opening that is disposed opposite the base wall and that is surrounded by the side wall; and a cover support surface that is formed by the side wall and on which a cover can be placed to close the hollow body, wherein the device comprises a support wall on which the hollow body can be placed; at least one passage opening formed by the support wall; and a cleaning device by which a cleaning fluid for cleaning the cover support surface can be dispensed when the hollow body is placed on the support wall; wherein the cleaning device has a cleaning head that projects over the passage opening when the hollow body is placed on the support wall; and has a number of cleaning nozzles through which the cleaning fluid can be applied to the cover support surface.

A support surface of the hollow body is placed onto the support wall and is optionally locked so that the hollow body is fixed in its position with respect to the support wall. It must be noted here that the support wall does not correspond to the cover support surface. It is rather assumed in the following that the cover support surface is a part of the inner hollow body surface and is formed by the side wall of the hollow body.

Due to the fact that the cleaning head is equipped with cleaning nozzles that are especially designed for the cleaning of the cover support surfaces, it is possible to clean the cover support surface very thoroughly so that contaminants that can be deposited on the semiconductor wafers are extensively eliminated. As a consequence, the number of defective and unusable production batches of semiconductor wafers can be considerably reduced in comparison with devices from the prior art.

In accordance with a further embodiment, the cleaning head can have a number of drying nozzles by which a drying gas can be applied to the cover support surface. In this embodiment, the device in accordance with the proposal can be used not only for cleaning, but also for the subsequent drying of the hollow body. To conclude the cleaning process, the supply of the cleaning fluid is stopped and instead a drying gas, air or nitrogen, for example, by which the cover support surface is dried, is conveyed toward the drying nozzles. The residues of the cleaning fluid still remaining on the cover support surface are removed by the drying gas.

In a further developed embodiment, the cleaning head can be rotationally or translationally movable. It is possible to react to geometrical special features of the cover support surface due to the movability of the cleaning head. It is in particular possible to apply the first cleaning fluid at least approximately perpendicular to the cover support surface, whereby the kinetic energy of the cleaning fluid can be particularly effectively used to clean the cover support surface.

In a further developed embodiment, the cleaning fluid and/or the drying gas can be dispensed at a spray angle, with the cleaning head having a setting device that cooperates with the cleaning nozzles and/or with the drying nozzles and by which the spray angle can be set. The spray angle at which the first cleaning fluid is dispensed also determines the angle at which the cleaning fluid impinges on the cover support surface. An angle of 90° or of approximately 90° is ideal Due to the fact that the spray angle can be set, the geometry of the inner hollow body surface can be modeled in that the first cleaning fluid can be applied almost over the cover support surface and adjacent regions of the inner hollow body surface at an angle of 90° or approximately 90°. The inner hollow body surface typically has labyrinthine points so that shading may occur with non-adjustable cleaning nozzles in which no amount or only a limited amount of the cleaning fluid can be applied to the inner hollow body surface and in particular to the cover support surface and to adjacent regions with sufficient kinetic energy. Such shading can be avoided in this embodiment so that the cleaning result is improved overall.

In a further embodiment, the cleaning head can have a number of infrared diodes by which the cover support surface can be heated. The cover support surfaces can be heated by the infrared diodes, whereby the drying process that is carried out using the drying gas is supported. The residues of the cleaning fluid still remaining on the cover support surface are removed as a result of the heating.

A further developed embodiment can be characterized in that the cleaning head has an outer shape that at least approximately follows the course of the inner hollow body surface so that the distance between the inner hollow body surface and the cleaning head is constant or almost constant. It has been found that a distance between 1 mm and 50 mm and in particular between 10 mm and 30 mm is ideal for a good cleaning result. A small distance contributes to generating a strong, directed flow in the intermediate space between the inner hollow body surface and the cleaning head, which has the consequence of a particularly good cleaning and drying effect. The distance here does not always have to be the same in the total intermediate space, but can also vary, which is of advantage, for example, when the side wall forms projections, recesses, and/or undercuts. It can be preferred here if the cleaning head is only largely complementary to the course of the inner hollow body surface such that its outer shape does not follow individual projections and/or recesses of the side wall. The cleaning head can be retracted into the inner space more simply and faster in these cases without the cleaning and/or drying effect being negatively impaired.

In accordance with a further embodiment, the device can have at least one coupling unit for coupling sound waves into the cleaning fluid. In this respect, the sound waves can in particular be ultrasound waves or megasound waves. While ultrasound waves have a frequency range of approximately 20 kHz to 500 kHz depending on the definition, megasound waves have a frequency range of approximately 500 kHz to 3 MHz It appears suitable here to wet the inner hollow body surface completely with the cleaning fluid or to flood the intermediate space between the cleaning head and the inner hollow body surface and to couple the sound waves into the cleaning fluid. The cleaning fluid then serves as a carrier of the sound waves. The cleaning effect is increased due to the fact that a specific amount of energy is hereby carried into the cleaning fluid since particles adhering to the cover support surface can hereby be particularly easily released. The energy input increases with the frequency of the sound coupled in. On the use of megasound, the advantage results that the energy can be brought to the cover support surface to be cleaned in a very targeted manner so that good cleaning results can be achieved.

It may be suitable in a further embodiment that at least some of the coupling units are integrated in or cooperate with at least some of the cleaning nozzles. In this case, the cleaning nozzles can be designed as so-called “megasonic nozzles” that make it possible to couple the sound waves into the first cleaning fluid dispensed by the first cleaning nozzles. It is then not necessary to wet the total inner hollow body surface with the first cleaning fluid, whereby the amount of the required first cleaning fluid can be kept small.

In a further developed embodiment, the device can comprise a first drainage channel having a first end, wherein the first end of the first drainage channel is only in fluid communication with the passage opening and by which the cleaning fluid dispensed by the cleaning device can be drained. In this embodiment, the cleaning fluid only comes into contact with the inner hollow body surface. The outer hollow body surface is typically contaminated more than the inner hollow body surface, but the influence of the contaminants on the inner hollow body surface on the number of defective product batches of semiconductor wafers is greater in comparison with contaminants on the outer hollow body surface inter alia due to the small spatial distance between the contaminants on the inner hollow body surface and the semiconductor wafers. Since the cleaning fluid can only come into contact with the inner hollow body surface in this embodiment, it is not contaminated by contaminants of the outer hollow body surface. The cleaning effect of the cleaning fluid is to this extent not thereby reduced.

In a further embodiment, a particle measuring device for determining the particles contained in the cleaning fluid can be arranged in the drainage channel. As mentioned, the cleaning fluid only comes into contact with the inner hollow body surface and consequently also with the cover support surface. Since the cleaning nozzles are configured to clean the cover support surface, it may be assumed that the particles that are registered by the particle measuring device originate only or to a greater extent from the cover support surface. The particle measuring device can count the number of particles, for example. If the number falls below a certain threshold value, this can be considered a criterion that the hollow body has been cleaned to a sufficient extent. The cleaning process can then be terminated. Time and cleaning fluid can hereby be saved.

In accordance with a further embodiment, the cleaning head can have a number of further cleaning nozzles for cleaning the inner hollow body surface. The further cleaning nozzles can be of an identical design to the cleaning nozzles by which the cover support surface is cleaned. However, they are arranged on the cleaning head such that the cleaning fluid dispensed from them does not impinge on the cover support surface. The remaining inner hollow body surface can be cleaned and the number of defective and unusable production batches of semiconductor wafers can be further reduced by the further cleaning nozzles.

In a further embodiment, the cleaning head can comprise a flexible sheath that can be changed from a contracted state into an expanded state and back by the cleaning fluid and/or by the drying gas. The cleaning nozzles, the drying nozzles, and/or the further cleaning nozzles can here be formed as simple holes or perforations of the flexible sheath. Alternatively, the sheath can be formed as a membrane. It is thus ensured that the cleaning fluid and/or the drying gas introduced into the sheath can exit the cleaning head and over the cover support surface and/or the inner hollow body surface. The flexible sheath is designed here such that a certain flow resistance, that has first to be overcome so that the cleaning fluid and/or the drying gas can exit the sheath again through the holes or perforations, is produced on the introduction of the cleaning fluid and/or of the drying gas into the flexible sheath. This flow resistance produces an accumulation of the cleaning fluid or of the drying gas in the sheath as a result of which the sheath is changed from the contracted state into the expanded state. The dimension of the sheath in the expanded state can be varied within certain limits by the pressure at which the cleaning fluid and/or the drying gas is/are introduced into the sheath. To this extent, the distance between the inner hollow body surface and the cleaning head can be set and can be adapted to differently shaped hollow bodies.

An embodiment of the invention relates to a method of cleaning pot-shaped hollow bodies, in particular transport containers for semiconductor wafers or for EUV lithography masks, using a device in accordance with one of the previous claims, said method comprising the following steps: placing the hollow body onto the support wall; dispensing a cleaning fluid to clean the cover support surface by means of a number of cleaning nozzles arranged on the cleaning head of the cleaning device such that the cleaning fluid is applied to the cover support surface; and draining the cleaning fluid by means of the drainage channel.

The technical effects and advantages that can be achieved with the proposed method correspond to those that have been discussed for the present device. It must be pointed out in summary that the cover support surface can be cleaned in a targeted manner. As mentioned, the cover support surface has a considerable influence on the number of effective and unusable production batches of semiconductor wafers. The number can be considerably reduced in comparison with processes known from the prior art due to the targeted cleaning of the cover support surface.

Provision can be made in a further embodiment that the method comprises the following steps: determining the particles contained in the cleaning fluid by means of the particle measuring device arranged in the drainage channel; and ending the dispensing of the cleaning fluid when a threshold value related to the particles is fallen below or exceeded.

The particle measuring device can, for example, determine the number and/or a particle diameter. In addition, a threshold value related thereto can be defined whose falling below or exceeding may be an indication that the hollow body has been sufficiently cleaned and that the cleaning procedure can be ended. It can, on the one hand, be documented that a certain hollow body has actually been cleaned to a sufficient degree and, on the other hand, the cleaning procedure can be ended when the hollow body is sufficiently clean.

A further developed embodiment can specify that the method comprises the following steps: fully flooding the intermediate space between the cleaning head and the inner hollow body surface with the cleaning fluid; and coupling sound waves into the cleaning fluid by means of a coupling unit.

The sound waves can, for example, be coupled in the form of ultrasound or megasound. The cleaning result is hereby improved since energy is hereby introduced into the first cleaning fluid and serves the release of the particles on the inner hollow body surface.

A further embodiment can specify that the method comprises the following steps: cleaning the cover support surface using the cleaning nozzles; and time-offset cleaning of the inner hollow body surface using the further cleaning nozzles.

As mentioned, the particles contained in the cleaning fluid can be determined, and, for example, counted by means of the particle measuring device on the flowing through of the draining channel. It can be assumed that particles that are removed on the cleaning of the cover support surface using the cleaning nozzles originate at least to a larger part from the cover support surface. The same applies correspondingly to the cleaning of the inner hollow body surface. Within the further cleaning nozzles, some cleaning nozzles can also be activated time offset from the other further cleaning nozzles. A statement can hereby be made whether certain regions of the inner hollow body surface are contaminated more than other regions and in particular more than the cover support surface or not. Defects in the production routine of the semiconductor wafers can be concluded from this.

### BRIEF DESCRIPTION OF THE DRAWINGS

Exemplary embodiments of the invention will be explained in more detail in the following with reference to the enclosed drawings. There are shown FIG. 1 depicts a basic sectional representation through a device in accordance with the prior art for cleaning pot-shaped hollow bodies, in particular transport containers for semiconductor wafers or for EUV lithography masks.

FIG. 2 depicts an enlarged representation, not to scale, of the detail A defined in FIG. 1.

FIG. 3 depicts a basic sectional representation through an embodiment of a device in accordance with the invention for cleaning pot-shaped hollow bodies, in particular transport containers for semiconductor wafers or for EUV lithography masks.

FIG. 4A depicts a basic sectional representation through a second embodiment of a device in accordance with the invention for cleaning pot-shaped hollow bodies, wherein the flexible sheath is at a contracted state.

FIG. 4B depicts a basic sectional representation through a second embodiment of a device in accordance with the invention for cleaning pot-shaped hollow bodies, wherein the flexible sheath is at an expanded state.

### DETAILED DESCRIPTION

A more detailed description of the invention provided herein will now be provided. The present invention will be described in connection with numerous embodiments. Such discussion is for purposes of illustration only and not intended to be limitative of the invention. Modifications to particular embodiments within the spirit and scope of the present invention, set forth in the appended claims, will be readily apparent to those of skill in the art. Accordingly, it is to be understood that the following disclosure describes several exemplary embodiments for implementing different features, structures, or functions of the invention. Exemplary embodiments of components, arrangements, and configurations are described below to simplify the present disclosure; however, these exemplary embodiments are provided merely as examples and are not intended to limit the scope of the invention.

The scope of the invention is defined in the appended claims, which for infringement purposes is recognized as including equivalents to the various elements or limitations specified in the claims. Depending on the context, all references to the “invention” may in some cases refer to certain specific embodiments only. In other cases, it will be recognized that references to the “invention” will refer to subject matter recited in one or more, but not necessarily all, of the claims. Each of the inventions will now be described in greater detail below, including specific embodiments, versions and examples, but the inventions are not limited to these embodiments, versions or examples, which are included to enable a person having ordinary skill in the art to make and use the inventions, when the information in this disclosure is combined with publicly available information and technology.

An embodiment of a device 10 in accordance with the prior art described, for example, in DE 10 2020 129 469 A1 for the cleaning of pot-shaped hollow bodies 12 is shown in FIG. 1 with reference to a basic sectional representation. The device 10 has a housing 14 that forms a housing opening 16 that is closable by a cover 18 removable from the housing 14. A support wall 20 is furthermore arranged in the housing 14 so that a closed process space 22 is provided in the housing 14. The process space 22 is bounded by the support wall 20, by the housing 14 itself, and by the cover 18. The support wall 20 forms a passage opening 24, with a locking device 26 being arranged radially outside the passage opening 24. Two passage bores 28 are provided in the support wall 20 radially outside the locking device 26 in the embodiment shown.

With a removed cover 18, a hollow body 12, in particular a transport container 30 for semiconductor wafers, also called FOUPs, or a transport container 30 for EUV lithium masks, can be introduced into the process space 22. The hollow body 12 has a base wall 32 and, in this case, four side walls 34 so that the pot-shaped hollow body 12 is substantially parallelepiped-shaped. It is, however, by all means possible to provide the pot-shaped hollow body 12 with a different geometry, for example a cylindrical geometry. The base wall 32 and the four side walls 34 form an inner hollow body surface 33 and an outer hollow body surface 35.

The hollow body 12 has an opening 36 that is arranged disposed opposite the base wall 32 and that is surrounded by a marginal surface 38 that is formed by the side walls 34. The hollow body 12 is designed in the manner of a flange in the region of the marginal surface 38 in the embodiment shown. The marginal surface 38 of the hollow body 12 can be placed onto the support wall 20. The passage opening 24 of the support wall 20 and the opening 36 of the hollow body 12 are at least approximately of the same size and of the same geometrical shape in the embodiment shown.

The locking device 26 is furthermore configured such that the passage opening 24 is at least approximately flush with the section of the inner hollow body surface 33 adjoining the passage opening 24.

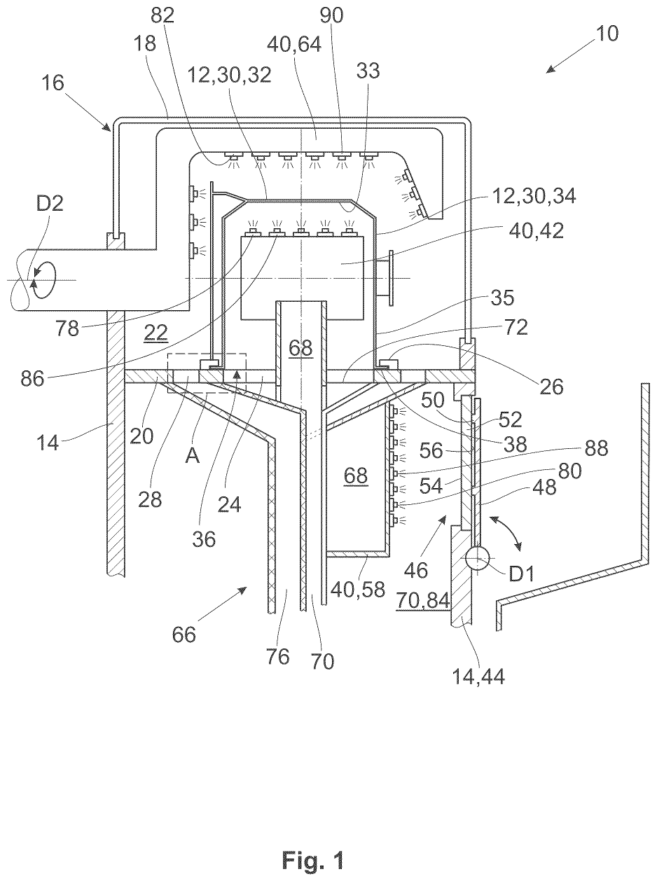

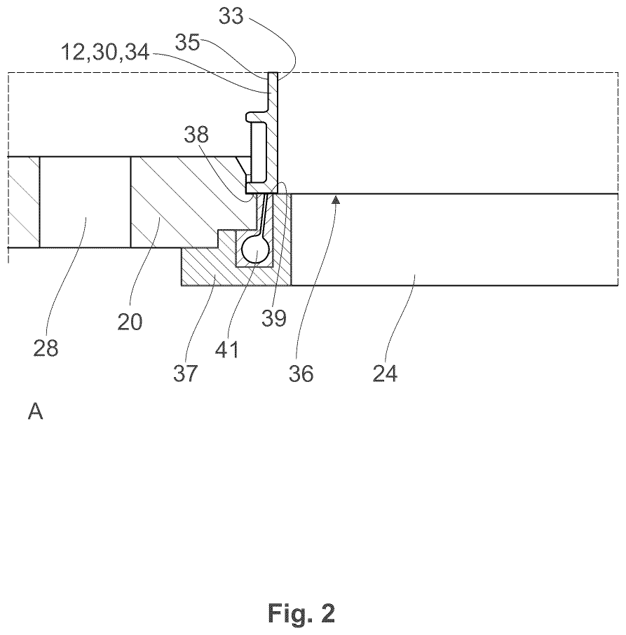

The region A marked in FIG. 1 is not shown enlarged to scale in FIG. 2, with no exact agreement being present. For illustration reasons, the locking device 26 is not shown. It can be recognized from FIG. 2 that the support wall 20 comprises a support wall section 37 that forms a contact surface 39 that is in contact with the marginal surface 38 of the transport container 30. In this respect, the contact surface 39 of the support wall section 37 is completely covered by the marginal surface 38. A first channel 41 is arranged in the support wall section 37 that opens into the contact surface 39 and by which a flushing fluid, for example air or nitrogen, can be conducted to the marginal surface 38.

The device 10 is furthermore equipped with a cleaning device 40 that has a first cleaning head 42 that projects over the passage opening 24 and is thus arranged within the process space 22. When the hollow body 12 is connected to the support wall 20, the first cleaning head 42 is surrounded by the hollow body 12.

The housing 14 further comprises a wall section 44 in which a cleaning opening 46 is arranged. The wall section 44 is located at the side of the support wall 20 remote from the locking device 26. The cleaning opening 46 is at least partially closable by a closure body 48 that is rotatably fastened to the wall section 44 about a first rotational axis D1 by a drive unit, not shown. The closure body 48 can be moved between an open position in which the closure body 48 releases the cleaning opening 46 and a closure position in which the closure body 48 at least partially closes the cleaning opening 46. The closure body 48 is in the closure position in FIG. 1.

The closure body 48 has a reception unit 50 by which a cover 52 by which the hollow body 12 is closable can be releasably fastened to the closure body 48. The cover 52 forms an inner cover surface 54 and an outer cover surface 56. The inner cover surface 54 is here that side of the cover 52 that directly adjoins the inner hollow body surface 33 when the hollow body 12 has been closed by the cover 52. In other words, the inner cover surface 54 in this case faces toward the base wall 32 of the hollow body 12.

The reception unit 50 is designed in the embodiment shown such that it only interacts with the cover 52 by means of the outer cover surface 56.

The cleaning device 40 is additionally equipped with a further first cleaning head 58 that is arranged in the vicinity of the closure body 48 when it is in the closure position.

The cleaning device 40 moreover comprises a second cleaning head 64 that is formed substantially in U shape and is at least partially arranged in the process space 22. Unlike the first cleaning head 42, however, the second cleaning head 64 is arranged outside the hollow body 12 when the hollow body 12 is connected to the support wall 20 as shown in FIG. 1. The second cleaning head 64 is rotatable about a second rotational axis, with the drive device used for this purpose not being shown. An embodiment is furthermore not shown in which the second cleaning head 64 is not only rotationally movable, but also translationally, or only translationally. In the embodiment shown, the first cleaning head 42 is not movable; however, it can also be designed as rotationally and/or translationally movable.

The device 10 is furthermore provided with a fluid conducting unit 66 by which a first cleaning fluid can be conducted to the first cleaning head 42 and to the further first cleaning head 58 and a second cleaning fluid can be conducted to the second cleaning head 64. The fluid conducting element 66 has a first supply channel 68 by which the first cleaning fluid can be conducted to the first cleaning head 42.

A detailed representation of a second supply channel for supplying the second cleaning fluid to the second cleaning head 64 has been dispensed with for illustration reasons, but is design should be easily deducible for the skilled person.

The fluid conducting unit 66 furthermore comprises a first drainage channel 70 by which the first cleaning fluid dispensed by the first cleaning head 42 and by the further first cleaning head 58 can be drained from the process space 22 again. The first drainage channel 70 has a first end 72 that is in fluid communication with the passage opening 24. As can be seen from FIG. 1, the first drainage channel 70 is expanded in funnel shape toward the first end 72 and is connected to the support wall 20 such that the first end 72 of the drainage channel terminates flush with the passage opening 24.

The fluid conducting unit 66 furthermore has a second drainage channel 76 that is designed substantially exactly the same as the first drainage channel 70; however, with the two passage bores 28 being in fluid communication. In this respect, the first drainage channel 70 forms the radially inner wall of the second drainage channel 76 so that the fluid conducting unit 66 can have a very compact design. It must be pointed out at this point that the fluid conducting unit 66 is only shown in principle in FIG. 1. The representation of the fluid conducting unit 66 in accordance with FIG. 1 does not make any claim to correctness due to the plurality of channels arranged nested and at different levels. At the same time, a flushing fluid is conducted through the first channel 41 to the marginal surface 38 and/or through the second channel 57 to the cover 52. It can be the same flushing fluid here, but it is also possible to conduct a first flushing fluid through the first channel 41 and a second flushing fluid different from the first flushing fluid through the second channel 57. The flushing fluid that is conducted through the first channel 41 to the marginal surface 38 provides that neither the first cleaning fluid nor the second cleaning fluid can traverse the marginal surface. The flushing fluid therefore effects a fluidic seal between the first cleaning fluid and the second cleaning fluid. It is consequently ensured that the first cleaning fluid and the second cleaning fluid cannot mix. A contamination of the first cleaning fluid by the second cleaning fluid and vice versa is prevented. However, it must be pointed out at this point that the flushing fluid has no or only a very limited cleaning effect on the marginal surface 38.

The first cleaning fluid that has been dispensed by the first cleaning head 42 and has been applied to the inner hollow body surface 33 is drained over the first drainage channel 70. The same also applies to the first cleaning fluid that has been dispensed by the further first cleaning head 58 and has been applied to the inner cover surface 54. The first drainage channel 70 has a secondary channel 84 that opens into the first drainage channel 70 to drain the first cleaning fluid that is used to clean the inner cover surface 54.

The flushing fluid that is conducted to the cover 52 flows through the gap 60 back into the secondary channel 84. The housing seal 61 prevents the flushing fluid from being able to enter into the environment. It is prevented by the flushing fluid that the first cleaning fluid that has been dispensed by the further first cleaning head 58 and has been applied to the inner cover surface 54 can reach the cover seal 53 to which particles in the first cleaning fluid can adhere.

The flushing fluid that is conducted to the marginal surface 38 and/or to the cover 52 can be sufficiently greatly pressurized.

Particles that were located on the inner hollow body surface 33 and on the inner cover surface 54 are removed by the first cleaning fluid. The second cleaning fluid that has been dispensed by the second cleaning head 64 and has been applied to the outer hollow body surface 35 is removed over the second drainage channel 76. Consequently, the first cleaning fluid and the second cleaning fluid are drained separately from one another as a result of which particles that originate from the outer hollow body surface 35 cannot enter into the first cleaning fluid and thus not onto the inner hollow body surface 33 or onto the inner cover surface 54.

If the inner hollow body surface 33 and the inner cover surface 54 have been cleaned to the desired degree, the cleaning process can be terminated independently of the degree to which the outer hollow body surface 35 has been prepared.

A first drying gas and a second drying gas, for example air or nitrogen, can now be conducted over the first supply channel 68 or over a second supply channel not shown here in largely the same manner as the first and second cleaning fluids to the first cleaning head 42, to the further first cleaning head 58, and to the second cleaning head 64. The first cleaning head 42 has first drying nozzles 86, the further first cleaning head 58 has further first drying nozzles 88, and the second cleaning head has second drying nozzles 90 by which the first drying gas or the second drying gas can be dispensed and applied to the inner hollow body surface 33, to the inner cover surface 54, and to the outer hollow body surface 35. The first drying gas and the second drying gas displace the first cleaning fluid and the second cleaning fluid from the device 10. Residues of the first and second cleaning fluids can moreover be blown away.

After the termination of the drying process, the cover 18 is opened and the closure body 48 is moved into the open position. The cleaned hollow body 12 is removed from the process space. The reception unit 50 is deactivated, as a result, the cover 52 can be removed from the closure body 48 and supplied to the hollow body 12 for the closing thereof. A further hollow body 12 to be cleaned can now be treated in the described manner in the device 10.

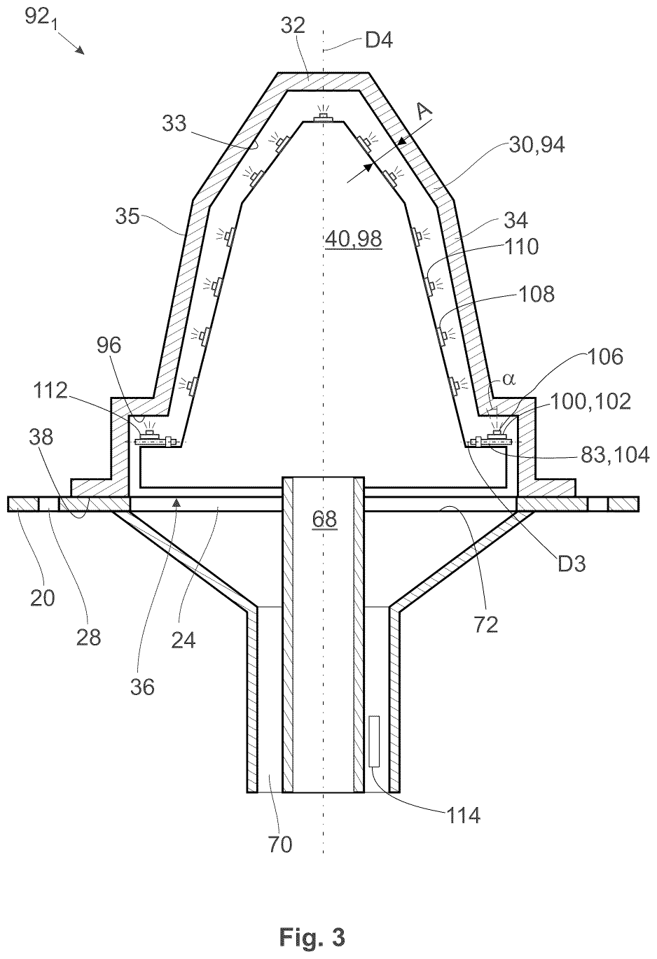

A first embodiment of a device 921 in accordance with a proposal for cleaning pot-shaped hollow bodies 94 is shown with reference to a basic sectional representation in FIG. 3. The essential design and the manner in which the device 921 in accordance with the proposal can be operated substantially correspond here to those that have been described for the device 10 in accordance with the prior art shown in FIGS. 1 and 2. Only the features material to the invention are therefore shown in FIG. 3.

If the hollow body 12 that can be cleaned using the device 10 shown in FIGS. 1 and 2 is compared with the hollow body 94 that is to be cleaned using the device 921 in accordance with the proposal, it can be found that the last-named hollow body 94 has, in addition to the marginal surface 38, a cover support surface 96 that is a part of the inner hollow body surface 33 and that is formed by means of a step of the side wall 34.

The cleaning device 40 has a cleaning head 98 that is equipped with a number of cleaning nozzles 100 through which the cleaning fluid can be applied to the cover support surface 96. The cleaning head 98 is furthermore equipped with drying nozzles 102 through which a drying gas can be applied to the cover support surface 96. The cleaning nozzles 100 and the drying nozzles 102 can be of the same design so that no difference has been made in the drawing in FIG. 3. The cleaning nozzles 100 can also be formed such that both the cleaning fluid and the drying gas can be applied to the cover support surface 96 by them.

The cleaning nozzles 100 and/or the drying nozzles 102 cooperate with a setting device 104 by which a spray angle a can be set at which the cleaning fluid and/or the drying gas is/are dispensed. The cleaning nozzles 100 and the drying nozzles 102 can be stored in the manner of golf balls for this purpose. Alternatively or accumulatively, in particular the cleaning nozzles 100 can be arranged on a tubular body 83 rotatable about a third rotational axis D3 so that the spray angle a can be set. It can hereby be achieved that the cleaning fluid and/or the drying gas impinges/impinge on the cover support surface 96 in a perpendicular or almost perpendicular manner.

The device 921 furthermore has at least one coupling unit 106 for coupling sound waves into the cleaning fluid. In the embodiment shown, some of the coupling units 106 are integrated in at least some of the cleaning nozzles 100 and are designed as so-called “megasonic nozzles”. A megasound can be coupled into the cleaning fluid dispensed by the cleaning nozzles 100.

In addition, further cleaning nozzles 108 are arranged on the cleaning head 98 by which the cleaning fluid can be applied to the inner hollow body surface 33. In the embodiment shown, the further cleaning nozzles 108 are of the same design as the cleaning nozzles 100 by which the cover support surface 96 can be cleaned. They can in particular also cooperate with the setting device 104 by which the spray angle α can be set (not shown). In addition, further drying nozzles 110 can be provided at the cleaning head 98.

The cleaning nozzles 100 and the further cleaning nozzles 108 can be opened and closed independently of one another. It is consequently possible to clean different sections of the inner hollow body surface 33 first and other sections later. For example, sections that are less soiled according to experience can be cleaned first and sections that are more soiled according to experience can be subsequently cleaned.

The cleaning head 98 can be moved translationally and/or rotationally along or about a fourth rotational axis D4 by means of a drive device, not shown. The cleaning head 98 furthermore has a number of infrared diodes 112 by which the cover support surface 96 can be heated. Further infrared diodes 112, not shown, can also be arranged at the cleaning head 98 to heat the remaining inner hollow body surface 33.

The cleaning head 98 has an outer shape that at least approximately follows the course of the inner hollow body surface 33 so that the distance A between the inner hollow body surface 33 and the cleaning head 98 is constant or almost constant. The endeavor here is to select the distance A to be as minimal as possible to generate a strong and clearly directed flow of the cleaning fluid and/or of the drying gas in the intermediate space between the inner hollow body surface 33 and the cleaning head 98, on the one hand, and to minimize the volume of the intermediate space, on the other hand, to keep the volume of cleaning fluid and drying gas required as small as possible. In the embodiment shown, the distance A should be between 10 mm and 30 mm. The intermediate space is here designed in the manner of an annular gap.

A particle measuring device 114 for determining the particles contained in the cleaning fluid is furthermore arranged in the first drainage channel 70.

As mentioned, the device 921 in accordance with the invention can be operated in substantially the same manner as the one from the prior art that was described in FIGS. 1 and 2. It must, however, be noted that the cover support surface 96 can be cleaned with a time offset from the remaining inner hollow body surface 33. When the cover support surface 96 is being cleaned, it can be assumed that the particles in the cleaning fluid on the flowing through of the first drainage channel 70 come from the cover support surface 96. The particles can be characterized by the particle measuring device 114 with respect to a relevant parameter, for example with respect to the number of particles. As soon as a threshold value of the number of particles with respect to a time unit has been fallen below, the supply of cleaning fluid to the cover support surface 96 can be interrupted. The remaining inner hollow body surface 33 can now be cleaned using the further cleaning nozzles 108. The supply of the cleaning fluid can also be stopped here if, for example, the number of particles in the cleaning fluid falls below a certain threshold value when flowing through the first drainage channel 70. The cleaning head 98 can be rotated about a fourth rotational axis D4 and moved along it when cleaning both the cover support surface 95 and the inner hollow body surface 33. In addition, the spray angle a can be varied by the setting device 104 and sound waves can be coupled into the cleaning fluid by the coupling unit 106.

A drying gas can subsequently be applied to the cover support surface 96 using the drying nozzles 102. At the same time or with a time offset, the cover support surface 96 can be heated by the infrared diodes 112. In this respect, the cleaning head 98 can also be rotated about the fourth rotational axis D2. After the hollow body 94 has been sufficiently dried, a further hollow body 94 to be cleaned can be treated in the described manner in the device 921. It should be noted at this point that the outer hollow body surface 35 and the cover 52 not shown in FIG. 3 can be treated substantially in an analog manner.

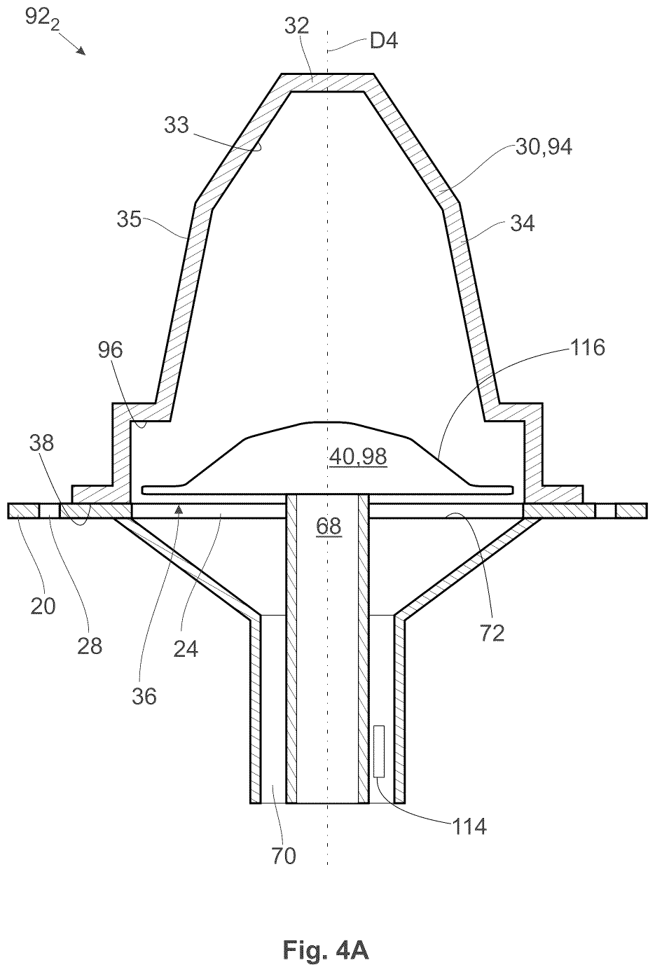

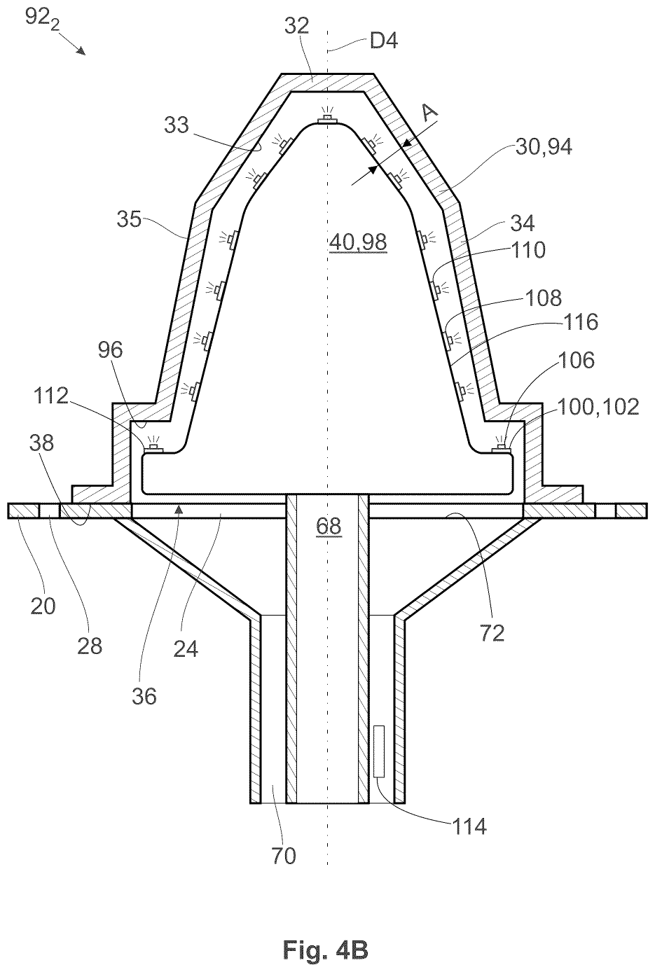

A second embodiment of a device 922 in accordance with a proposal for cleaning pot-shaped hollow bodies 94 is shown with reference to a basic sectional representation in FIGS. 4A and 4B. The essential difference from the embodiment of the device 921 shown in FIG. 3 is that the cleaning head 98 has a flexible sheath 116 that can be changed from a contracted state (FIG. 4A) into an expanded state (FIG. 4B) and back. Starting from the contracted state shown in FIG. 4A, the cleaning fluid or the drying gas is introduced through the supply channel 68 into the flexible sheath 116. As a result of this, the flexible sheath 116 fills with the cleaning fluid or the drying gas and expands continuously in so doing. The flexible sheath 116 expands for so long until the volume of the supplied cleaning fluid or drying gas is equal to the volume that leaves the flexible sheath 116 again through the cleaning nozzles 100, drying nozzles 102, and/or further cleaning nozzles 100. For reasons of illustration, the cleaning nozzles 100, drying nozzles 102, and/or further cleaning nozzles 108 are only shown in FIG. 4B. The flexible sheath 116 is then in the expanded state. The dimensions of the flexible sheath 116 in the expanded state can be selected within certain limits by the cleaning fluid or drying gas used and by the temperature and the pressure at which the cleaning fluid or drying gas is introduced into the flexible sheath 116. Since the cleaning fluid and the drying gas flow along the inner hollow body surface 33 in the intermediate space between the inner hollow body surface 33 and the cleaning head 98, it is prevented that the flexible sheath 116 can come into contact with the inner hollow body surface 33. To this extent, the flexible sheath 116 can also adapt within certain limits to the course of the inner hollow body surface 33, in particular also in regions of undercuts, so that a constant or almost constant distance A results that can be very largely minimized, which is only possible with limitations with a rigid cleaning head 98. As mentioned, the distance A amounts to between 10 mm and 30 mm with a rigid cleaning head 98. This distance A can be further reduced with a flexible sheath 116. As mentioned, a strong and clearly directed flow of the cleaning fluid and/or of the drying gas can be generated with a small distance A in the intermediate space between the inner hollow body surface 33 and the cleaning head 98 and the volume of required cleaning fluid and drying gas can be kept low. These advantages can be implemented to an even greater degree using a flexible sheath 116. As likewise mentioned, the flexible sheath 116 can adapt to the course of the inner hollow body surface 33 within certain limits. As a result of this, it is also possible to use the device for cleaning and/or drying differently shaped hollow bodies 94 without conversion work being necessary.

The foregoing has outlined features of several embodiments so that those skilled in the art can better understand the present disclosure. Those skilled in the art should appreciate that they can readily use the present disclosure as a basis for designing or modifying other methods or devices for carrying out the same purposes and/or achieving the same advantages of the embodiments disclosed herein. Those skilled in the art should also realize that such equivalent constructions do not depart from the spirit and scope of the present disclosure, and that they can make various changes, substitutions, and alterations herein without departing from the spirit and scope of the present disclosure, and the scope thereof is determined by the claims that follow.

To the extent a term used in a claim is not defined above, it should be given the broadest definition persons in the pertinent art have given that term as reflected in at least one printed publication or issued patent. Furthermore, all patents, test procedures, and other documents cited in this application are fully incorporated by reference to the extent such disclosure is not inconsistent with this application and for all jurisdictions in which such incorporation is permitted.

1-14. (canceled)

15. A device for drying and/or cleaning pot-shaped transport containers for semiconductor wafers or for EUV lithography masks, comprising:
a support wall on which a pot-shaped transport container can be placed, wherein each pot-shaped transport container comprises a base wall, one or more side walls that form an inner hollow body surface, an opening that is opposite the base wall and surrounded by the side wall, and a cover support surface adjacent the opening and on which a cover can be placed to close off the hollow body;
at least one passage opening formed through the support wall; and
a cleaning device configured to dispense a cleaning fluid at the cover support surface for cleaning the cover support surface when the transport container is placed on the support wall, wherein the cleaning device has at least one cleaning head that projects over the passage opening and/or can be introduced into the hollow body of the transport container when placed on the support wall, and wherein the cleaning device has a plurality of cleaning nozzles through which the cleaning fluid can be applied to the cover support surface.

16. The device of claim 15, wherein the at least one cleaning head has a plurality of drying nozzles by which a drying gas can be applied to the cover support surface.

17. The device of claim 16, wherein the at least one cleaning head is rotationally and/or translationally movable.

18. The device of claim 16, wherein the cleaning fluid and/or the drying gas is dispensed at a spray angle (α), with the cleaning head having a setting device that cooperates with the cleaning nozzles and/or with the drying nozzles and by which the spray angle (α) is set.

19. The device of claim 15, wherein the at least one cleaning head has a plurality of infrared diodes by which the cover support surface can be heated.

20. The device of claim 15, wherein the at least one cleaning head has an outer shape that at least approximately follows the course of the inner hollow body surface so that the distance between the inner hollow body surface and the cleaning head is constant or almost constant.

21. The device of claim 15, further comprising at least one coupling unit for coupling sound waves into the cleaning fluid.

22. The device of claim 15, further comprising a first drainage channel having a first end, with the first end of the first drainage channel only being in fluid communication with the passage opening, by which drainage channel the cleaning fluid dispensed by the cleaning device is drained and a particle measuring device for determining the particles contained in the cleaning fluid.

23. The device of claim 15, wherein the at least one cleaning head has a plurality of cleaning nozzles for cleaning the inner hollow body surface.

24. The device of claim 15, further comprising a flexible sheath that can be changed from a contracted state into an expanded state and back by the cleaning fluid and/or by the drying gas.

25. A method for drying and/or cleaning pot-shaped transport containers for semiconductor wafers or for EUV lithography masks, comprising:
providing a device that comprises a support wall, at least one passage opening formed through the support wall; a cleaning device configured to dispense a cleaning fluid, the cleaning device comprising a plurality of cleaning nozzles arranged about a cleaning head, and a drainage channel;
locating a pot-shaped transport container onto the support wall, wherein the pot-shaped transport container comprises a base wall, one or more side walls that form an inner hollow body surface, an opening that is opposite the base wall and surrounded by the side wall, and a cover support surface adjacent the opening and on which a cover can be placed to close off the hollow body;
dispensing the cleaning fluid through the cleaning device onto the cover support surface to clean the cover support surface; and
draining the cleaning fluid through the drainage channel.

26. The method of claim 25, wherein the cleaning head projects over the passage opening and/or can be introduced into the inner hollow body of the transport container when the transport container is placed on the support wall.

27. The method of claim 25, further comprising: determining a number of particles in the cleaning fluid using a particle measuring device located within in the drainage channel; and ending the dispensing of the cleaning fluid when a threshold value related to the particles is fallen below or exceeded.

28. The method of claim 25, further comprising flooding the inner hollow body with the first cleaning fluid; and coupling sound waves into the first cleaning fluid by means of a coupling unit.
